(19) United States
(12) Patent Application Publication
(10) Pub. No.: US 2016/0095202 A1
(43) Pub. Date: Mar. 31, 2016

(54) CIRCUIT BOARD AND MANUFACTURING METHOD THEREOF

(71) Applicant: Samsung Electro-Mechanics Co., Ltd., Suwon-Si (KR)

(72) Inventors: Tae Hong MIN, Suwon-Si (KR); Young Gwan KO, Seoul (KR); Jung Han LEE, Seoul (KR); Myung Sam KANG, Hwaseong-si (KR)

(73) Assignee: Samsung Electro-Mechanics Co., Ltd., Suwon-Si (KR)

(21) Appl. No.: 14/870,192

(22) Filed: Sep. 30, 2015

(30) Foreign Application Priority Data
Sep. 30, 2014 (KR) 10-2014-0130868

(51) Int. Cl. H05K 1/02; H05K 3/06; H05K 3/42; H05K 3/46; H05K 1/11; H05K 1/03

(52) U.S. Cl. CPC H05K 1/0206; H05K 1/0298; H05K 1/115; H05K 1/032; H05K 3/429; H05K 3/4644; H05K 1/0271; H05K 3/06; H05K 2201/09545; H05K 2201/068

(57) ABSTRACT

A circuit board includes a first metal layer having a first via hole penetrating through an upper surface of the first metal layer and a lower surface thereof; a plated part provided to a surface of the first via hole; an insulating film provided to a surface of the plated part; and a first via formed by providing a conductive material to at least a portion of a region surrounded by an outer surface of the insulating film. Since the circuit board may implement fineness of the first via while forming the first metal layer to be thicker than the related art, warpage may be decreased and heat dissipation performance may be improved.

### CROSS REFERENCE TO RELATED APPLICATION

This application claims priority to and the benefit of Korean Patent Application Serial No. 10-2014-0130868 entitled “Circuit Board and Manufacturing Method thereof” filed on Sep. 30, 2014 with the Korean Intellectual Property Office, which is hereby incorporated by reference in its entirety into this application.

### TECHNICAL FIELD

The present disclosure relates to a circuit board and a manufacturing method thereof.

### BACKGROUND

In accordance with a trend toward thinness and lightness, and high performance of an electronic device, so-called multilayer substrate technologies for forming a plurality of wiring layers on a circuit board such as a printed circuit board have been developed. Further, a technology for mounting electronic components such as active elements or passive elements on the multilayer substrate has also been developed.

For example, Patent Document 1 has disclosed a printed circuit board including electronic components inserted into cavities and a plurality of layers, and a manufacturing method thereof.

Meanwhile, in accordance with a trend toward slimness of the multilayer substrate, a flexure phenomenon of the substrate has become a serious problem. The flexure phenomenon is also referred to as warpage. As the multilayer substrate has been made of various materials having different coefficients of thermal expansion, the warpage has been intensified and a research for reducing such warpage has been continuously conducted.

Further, in accordance with a trend toward multifunction and high performance of an application processor (AP), or the like, connected to the multilayer substrate, thermal resistance has been significantly increased. As a result, an effort to improve decrease of the thermal resistance or improve heat dissipation performance has been devoted.

Further, in accordance with a trend toward miniaturization of active elements such as the application processor, and the like, a degree of integration has been increased and pitches of external connection terminals of the active elements has been fined. Therefore, a decrease in the pitches and an increase in the degree of integration of connection pads, wiring patterns, and vias included in the multilayer substrate on which the active elements are mounted have been required.

### RELATED ART DOCUMENT

### Patent Document

(Patent Document 1) U.S. 2012-0006469 A1

(Patent Document 2) KR 10-2010-0138209 A1

### SUMMARY

An object of the present disclosure is to provide a circuit board capable of fining vias penetrating through a metal layer and improving heat dissipation performance at the same time.

Another object of the present disclosure is to provide a manufacturing method of a circuit board capable of fining vias penetrating through a metal layer and improving heat dissipation performance at the same time.

Objects of the present disclosure are not limited to the above-mentioned objects. That is, other objects that are not mentioned may be obviously understood by those skilled in the art to which the present disclosure pertains from the following description.

According to an exemplary embodiment of the present disclosure, there is provided a circuit board including a first metal layer and a first via penetrating through the first metal layer.

A plated part and an insulating film may be provided between a surface of the first metal layer and a surface of the first via.

The plated part may be implemented by a multistage plating and may include a plurality of plated layers.

The insulating film may be implemented by parylene vapor deposition.

The first via hole may be implemented by a chemical etching scheme.

### BRIEF DESCRIPTION OF DRAWINGS

FIG. 1 is a cross-sectional view schematically illustrating a circuit board according to an exemplary embodiment of the present disclosure;

FIG. 2 is a cross-sectional view schematically illustrating a circuit board according to another exemplary embodiment of the present disclosure;

FIG. 3 is an enlarged cross-sectional view schematically illustrating part A of FIG. 1;

FIG. 4 is a diagram illustrating a process of forming a second via hole of a manufacturing method of a circuit board according to an exemplary embodiment of the present disclosure; and

FIG. 5 is a diagram illustrating a process of forming a first via of the manufacturing method of the circuit board according to an exemplary embodiment of the present disclosure.

### DETAILED DESCRIPTION

Various advantages and features of the present disclosure and methods accomplishing thereof will become apparent from the following description of exemplary embodiments with reference to the accompanying drawings. However, the present disclosure may be modified in many different forms and it should not be limited to exemplary embodiments set forth herein. These exemplary embodiments may be provided so that this disclosure will be thorough and complete, and will fully convey the scope of the present disclosure to those skilled in the art. Like reference numerals throughout the description denote like elements.

Terms used in the present specification are for explaining exemplary embodiments rather than limiting the present disclosure. Unless explicitly described to the contrary, a singular form includes a plural form in the present specification. The word ‘comprise’ and/or ‘comprising’ used in the present specification will be understood to imply the inclusion of stated components, steps, operations and/or elements but not the exclusion of any other components, steps, operations and/or elements.

For simplification and clearness of illustration, a general configuration scheme will be shown in the accompanying drawings, and a detailed description of the feature and the technology well known in the art will be omitted in order to prevent a discussion of exemplary embodiments of the present disclosure from being unnecessarily obscure. Additionally, components shown in the accompanying drawings are not necessarily shown to scale. For example, sizes of some components shown in the accompanying drawings may be exaggerated as compared with other components in order to assist in understanding of exemplary embodiments of the present disclosure. Like reference numerals on different drawings will denote like components, and similar reference numerals on different drawings will denote similar components, but are not necessarily limited thereto.

In the specification and the claims, terms such as “first”, “second”, “third”, “fourth”, and the like, if any, will be used to distinguish similar components from each other and be used to describe a specific sequence or a generation sequence, but are not necessarily limited thereto. It may be understood that these terms are compatible with each other under an appropriate environment so that exemplary embodiments of the present disclosure to be described below may be operated in a sequence different from a sequence shown or described herein. Likewise, in the present specification, in the case in which it is described that a method includes a series of steps, a sequence of these steps suggested herein is not necessarily a sequence in which these steps may be executed. That is, any described step may be omitted and/or any other step that is not described herein may be added to the method.

In the specification and the claims, terms such as “left”, “right”, “front”, “rear”, “top, “bottom”, “over”, “under”, and the like, if any, do not necessarily indicate relative positions that are not changed, but are used for description. It may be understood that these terms are compatible with each other under an appropriate environment so that exemplary embodiments of the present disclosure to be described below may be operated in a direction different from a direction shown or described herein. A term “connected” used herein is defined as being directly or indirectly connected in an electrical or non-electrical scheme. Targets described as being “adjacent to” each other may physically contact each other, be close to each other, or be in the same general range or region, in the context in which the above phrase is used.

Hereinafter, a configuration and an acting effect of exemplary embodiments of the present disclosure will be described in more detail with reference to the accompanying drawings.

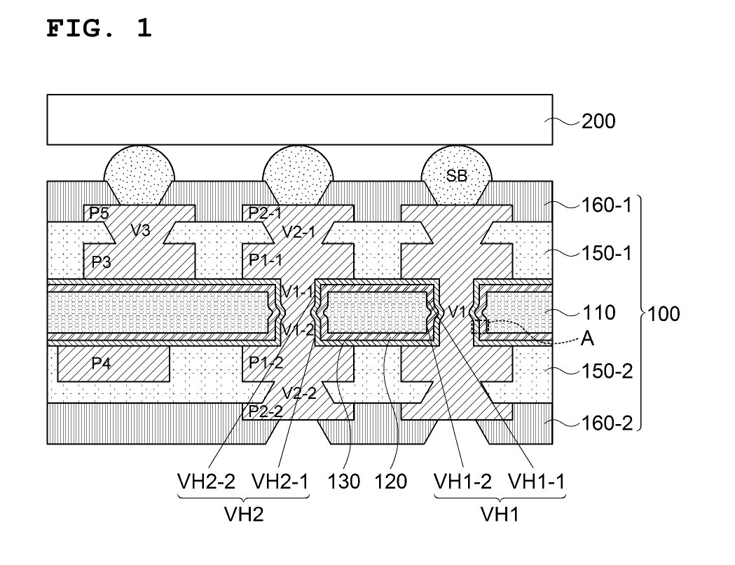

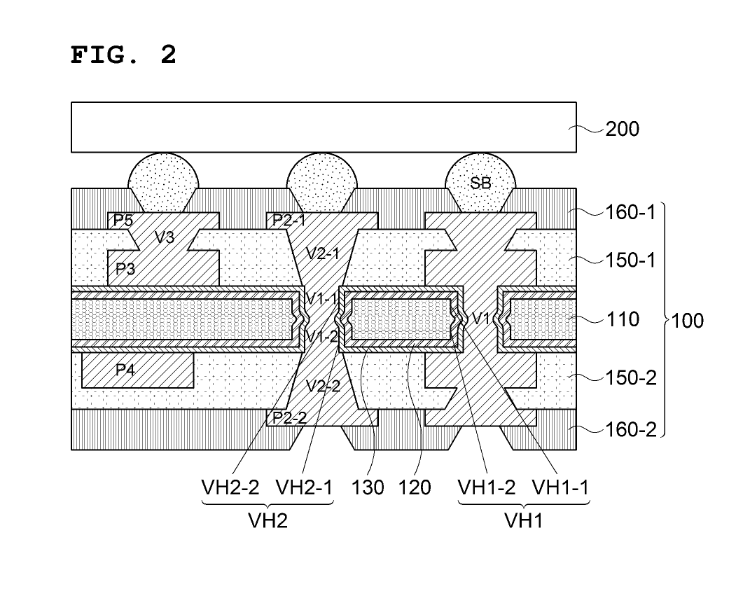

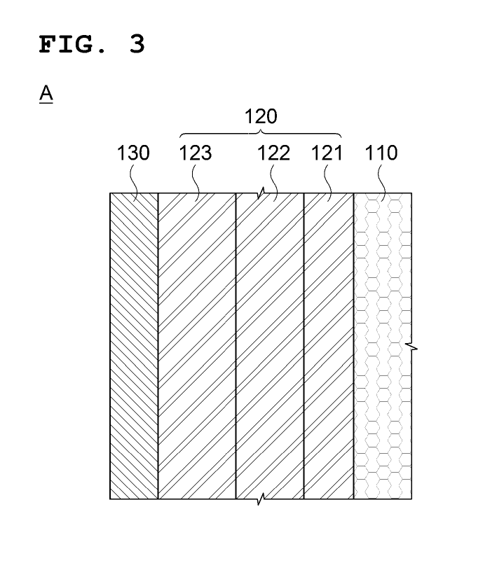

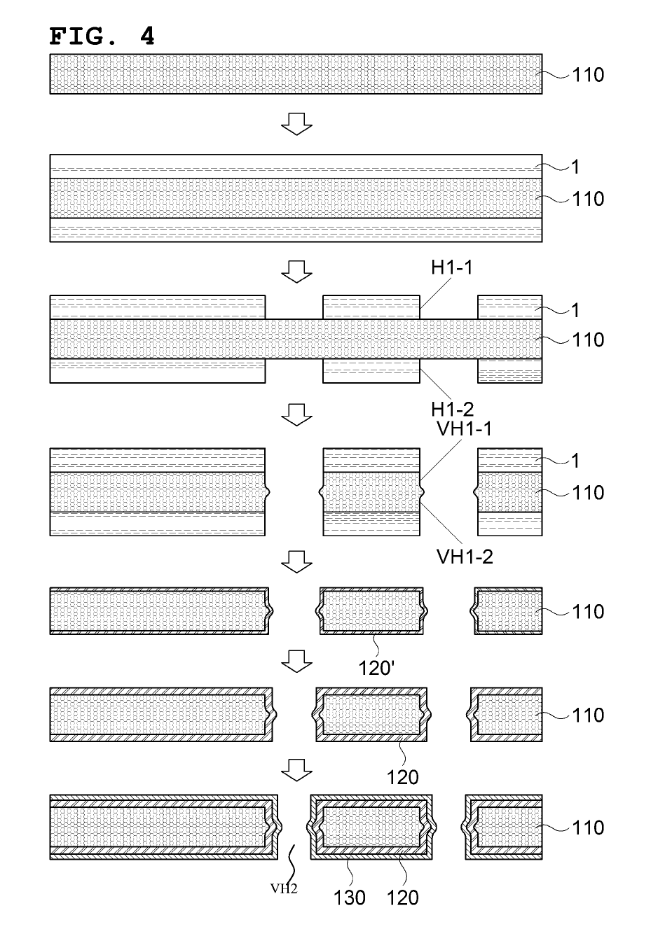

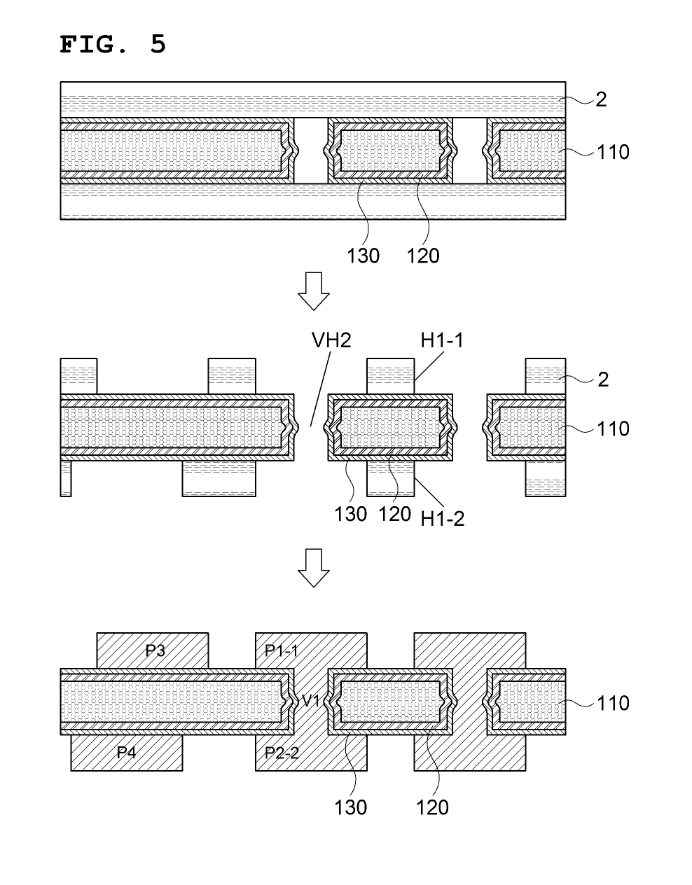

FIG. 1 is a cross-sectional view schematically illustrating a circuit board according to an exemplary embodiment of the present disclosure, FIG. 2 is a cross-sectional view schematically illustrating a circuit board according to another exemplary embodiment of the present disclosure, and FIG. 3 is an enlarged cross-sectional view schematically illustrating part A of FIG. 1. In addition, FIG. 4 is a diagram illustrating a process of forming a second via hole of a manufacturing method of a circuit board according to an exemplary embodiment of the present disclosure and FIG. 5 is a diagram illustrating a process of forming a first via of the manufacturing method of the circuit board according to an exemplary embodiment of the present disclosure.

A circuit board 100 according to an exemplary embodiment of the present disclosure has a plated part 120 and an insulating film 130 provided between vias penetrating through a metal layer and the metal layer. In this case, the plated part 120 may be formed by a multistage plating process.

Referring to FIG. 1, the circuit board 100 according to an exemplary embodiment of the present disclosure includes a first metal layer 110 and a first via V1. In this case, the circuit board 100 may further include an insulating layer or a wiring pattern, if necessary.

According to an exemplary embodiment, the first metal layer 110 may be provided between a first upper insulating layer 150-1 and a first lower insulating layer 150-2 so as to serve as a core. That is, the first metal layer 110 may serve to reduce warpage of the circuit board 100, since the first metal layer 110 may be much stiffer than a non-metal layer for forming a conventional circuit board. In addition, since the first metal layer 110 is made of a metal material and the metal material has higher heat conductivity than a general insulating material used to form a conventional circuit board, the first metal layer 110 may help improvement of heat dissipation performance of the circuit board 100.

Meanwhile, the first via V1 penetrates through the first metal layer 110 and serves as a path that electrically connects between an upper surface and a lower surface of the circuit board 100. In addition, the first via V1 may also serve as a heat transfer path between the upper surface and the lower surface of the circuit board 100.

According to an exemplary embodiment, the plated part 120 and the insulating film 130 are provided between a surface of the first via V1 and the first metal layer 110. That is, in a state in which the first via hole VH1 is provided in the first metal layer 110, the plated part 120 may be formed on a surface of the first metal layer 110 and the insulating film 130 may be formed on an outer surface of the plated part 120. In this case, the first metal layer 110 and the plated part 120 formed on the first metal layer 110 may be completely surrounded by the insulating film 130. Thus, the first metal layer 110 and the plated part 120 formed of a different metal from the first metal, may be electrically isolated from the first via V1 by the insulating film 130.

In addition, the first via V1 is formed in a region surrounded by an outer surface of the insulating film 130. Here, an inner portion of a region defined as a first via hole VH1 of the region surrounded by the outer surface of the insulating film 130 may be defined as a second via hole VH2. Therefore, it may be said that the first via V1 is formed in the second via hole VH2. In addition, a diameter of the second via hole VH2 is reduced as much as a thickness of the plated part 120 and a thickness of the insulating film 130 as compared to a diameter of the first via hole VH1.

According to an exemplary embodiment, the first via hole VH1 may be formed in the first metal layer 110 using a chemical etching process.

In this case, the etching process may be each performed for both surfaces of the first metal layer 110. For example, as illustrated in FIG. 4, in a state in which resists 1 are formed on both surfaces of the first metal layer 110, a first upper via hole VH1-1 may be formed by providing an etchant into a first opening part H1-1 and a first lower via hole VH1-2 may be formed by providing the etchant into a second opening part H1-2.

Since a diameter of the via hole becomes larger than a depth of the via hole in the case in which the via hole is formed by performing the etching process, if the first metal layer 110 has the same thickness, it is advantageous for the fineness of the via hole to form the first via hole VH1 by performing the etching in a direction from the upper surface of the first metal layer 110 to a lower surface thereof and also performing the etching in a direction from the lower surface of the second metal layer 110 to the upper surface thereof.

Meanwhile, if the etching process is performed in both directions of the first metal layer 110, the first upper via hole VH1-1 has a shape of which a width is decreased in the direction from the upper surface of the first metal layer 110 to the lower surface thereof and the first lower via hole VH1-2 has a shape of which a width is decreased in the direction from the lower surface of the first metal layer 110 to the upper surface thereof.

According to another exemplary embodiment, the first via hole VH1 may also be formed in the first metal layer 110 by a laser drilling method. The above-mentioned laser drilling method may advantageously fine the diameter or pitch of the via hole as compared to the chemical etching method described above. However, in the case in which a large number of via holes need to be machined by the laser drilling method, manufacturing efficiency is decreased as compared to the chemical etching process as described above. In addition, as the thickness of the first metal layer 110 is increased, an efficiency of forming the via hole by the laser drilling method is significantly decreased. Therefore, in the case in which the first metal layer 110 having a predetermined thickness or more is required to secure rigidity necessary to decrease warpage, or increase heat dissipation performance, the first via hole VH1 may be advantageously formed by the chemical etching method rather than the laser drilling method.

Meanwhile, in the case in which the first via hole VH1 is formed by using the chemical etching method, the diameter of the first via hole VH1 is proportional to the thickness of the first metal layer 110. It is preferable for the fineness of the via hole to use the chemical etching method rather than to use the laser drilling method, but in the case in which the thickness of the first metal layer 110 is increased, the diameter of the first via hole VH1 has no choice but to be also increased to some degree. Further, as described above, the laser drilling method also has a disadvantage that as the thickness of the first metal layer 110 becomes thick, process efficiency is significantly reduced.

In order to overcome the limit described above, the circuit board 100 according to an exemplary embodiment of the present disclosure has the plated part 120 provided on the first vial hole VH1. In addition, the insulating film 130 is provided on the surface of the plated part 120, so as to guarantee electrical insulation between the first via V1 and the first metal layer 110.

Referring to FIGS. 1 and 3, the first via V1 is formed so as to be in contact with the second via hole VH2 defined by the insulating film 130. Here, in the case in which the etching is performed for both surfaces of the first metal layer 110 or the laser drilling is performed for both surfaces of the first metal layer 110, the first upper via hole VH1-1 and the first lower via hole VH1-2 may be classified. In addition, in the case in which the first upper via hole VH1-1 and the first lower via hole VH1-2 are classified as described above, the second via hole VH2 defined by the insulating film 130 may also be defined as a second upper via hole VH2-1 and a second lower via hole VH2-2. In addition, a via formed in the second upper via hole VH2-1 may be defined as a first upper via V1-1 and a via formed in the second lower via hole VH2-2 may be defined as a first lower via V1-2, wherein the first upper via V1-1 and the second lower via V2-2 are integrated with each other, thereby making it possible to form the first via V1.

According to an exemplary embodiment, the plated part 120 may be formed by a multistage plating process. That is, after a first plated layer 121 is formed by performing a plating process on the surface of the first metal layer 110, a second plated layer 122 is formed by performing another plating process on a surface of the first plated layer 121. Here, the respective plated layers may be formed by a flash plating method. Although FIG. 3 illustrates the case in which the plated part 120 is formed of the first plated layer 121 to a third plated layer 123, only two plated layers may be formed or four or more plated layers may be formed, if necessary. That is, the number of plated layers may be adjusted taking account of the required diameter of the first via V1.

Meanwhile, the insulating film 130 may be implemented by vapor-depositing parylene on the surface of the plated part 120. As such, by implementing the insulating film 130 with the parylene deposition, the thickness of the insulating film 130 may be decreased as compared to a case in which a general insulating material is applied and an insulating means having a relatively uniform thickness may be provided on a surface of a fine via hole. As a result, a volume of the first via V1 may be maximally secured while the diameter of the first via V1 is fined, and insulation between the first metal layer 110 and the first via V1 may also be secured.

As described above, by forming the plated part 120 of which the thickness is adjusted by the multistage plating process on the surface of the first metal layer, particularly, the surface of the first via hole VH1, the diameter of the first via V1 may be finely adjusted. In addition, even in the case in which the via hole is formed in a relatively thick metal layer by the chemical etching process, since the diameter of the via may be reduced by adjusting the thickness of the plated part 120, the via penetrating through the metal layer may be fined.

Referring to FIG. 1, a first upper conductor pattern P1-1 or an upper internal layer pattern P3 may be provided on the first metal layer 110. In this case, in order to secure insulation between the first metal layer 110 and the first upper conductor pattern P1-1 or between the first metal layer 110 and the upper internal layer pattern P3, the insulating film 130 may also be provided on the first metal layer 110. In addition, the plated part 120 described above may also be provided between the insulating film 130 and the surface of the first metal layer 110. That is, the plated part 120 may also be provided on the upper surface of the first metal layer 110 in the process of forming the plated part 120 on the surface of the first via hole VH1. In addition, the insulating film 130 may also be provided on the upper surface of the plated part 120 formed on the upper surface of the first metal layer 110 in the process of forming the insulating film 130 on the plated part 120 formed on the surface of the first via hole VH1.

In addition, an insulating layer may be provided on the first metal layer 110. According to an exemplary embodiment, the first upper insulating layer 150-1 covering the first metal layer, the first upper conductor pattern P1-1 and the upper internal layer pattern P3 described above, and the like are provided. Here, the first upper conductor pattern P1-1 may be directly connected to the upper surface of the first via V1. In addition, the first upper conductor pattern P1-1 may also be formed so that the first via V1 and the first upper conductor pattern P1-1 are integrally formed in the process of forming the first via V1.

Meanwhile, a second upper conductor pattern P2-1, an upper external layer pattern P5, or the like may also be provided on an upper surface of the first upper insulating layer 150-1. In addition, a second upper via V2-1 penetrating through the first upper insulating layer 150-1 and connecting the second upper conductor pattern P2-1 and the first upper conductor pattern P1-1 may be provided. In addition, the upper external layer pattern P5 may be connected to the upper internal pattern P3 through a third via V3.

In this case, as illustrated in FIG. 2, the first upper conductor pattern P1-1 may not be provided, and in this case, the second upper conductor pattern P2-1 and the upper surface of the first via V1 may be connected to each other through the second upper via V2-1.

According to an exemplary embodiment, a second upper insulating layer 160-1 is further provided on the first upper insulating layer 150-1. In this case, the second upper insulating layer 160-1 may be implemented with a solder resist layer, and the second upper insulating layer 160-1 may expose a portion of the second upper conductor pattern P2-1 or a portion of the upper external layer pattern P5 to the outside of the circuit board 100. As such, the portion exposed to the outside of the second upper insulating layer 160-1 may be connected to other devices, for example, various components such as active elements, passive elements, another circuit board 100, and the like, and the above-mentioned device is illustrated as a first electronic component 200 in FIGS. 1 and 2. A surface treatment part such as nickel-gold plating, or the like may be provided to the portion exposed to the outside of the second upper insulating layer 160-1 of the portion of the second upper conductor pattern P2-1 or the portion of the upper external layer pattern P5, and may be physically or electrically connected to the first electronic component 200 by solder balls SB, wires, or the like. Therefore, the second upper conductor pattern P2-1 or the upper external layer pattern P5 may serve as a contact pad.

Meanwhile, although the upper portion of the first metal layer 110 is described above, similar components may also be provided to a lower portion of the first metal layer 110. That is, a first lower conductor pattern P1-2, a first lower insulating layer 150-2, a second lower via V2-2, a lower internal layer pattern P4, a second lower conductor pattern P2-2, a second lower insulating layer 160-2, and the like may be further provided.

Referring to FIGS. 1 to 5, a manufacturing method of a circuit board 100 according to an exemplary embodiment of the present disclosure includes a process of forming a via hole, a process of forming a plated part 120, a process of forming an insulating film 130, and a process of forming a via.

First, after a resist 1 is formed on a surface of a first metal layer 110, the resist of a portion in which a first via hole VH1 is to be formed is removed so as to form a first opening part H1-1 and a second opening part H1-2.

Next, a first upper via hole VH1-1 and a first lower via hole VH1-2 are formed by supplying an etchant into the first opening part H1-1 and the second opening part H1-2 formed in the resist 1.

Next, a plated part 120 is formed by using a flash plating method. In this case, a thickness of the plated part 120 may be adjusted by repeatedly performing the plating process.

Next, an insulating film 130 is formed on a surface of the plated part 120. Here, the insulating film 130 may be made of a parylene material and may be implemented with vapor deposition. In this case, a space surrounded by a surface of the insulating film 130 may be defined as a second via hole VH2.

Next, referring to FIG. 5, after a resist 2 is provided to the first metal layer 110 in which the second via hole VH2 is formed, the first opening part H1-1 and the second opening part H1-2 are formed by patterning the resist 2.

Next, a first via V1 is formed by using the patterned resist 2. In this process, an upper internal layer pattern P3 including a plurality of metal traces or a lower internal layer pattern P4 including a plurality of metal traces may be formed, and a first upper conductor pattern P1-1 and the first lower conductor pattern P1-2 may also be formed, if necessary.

Thereafter, the resist 2 may be removed, and a typical build-up process may be performed, if necessary.

According to the exemplary embodiments of the present disclosure, the maximum diameters or pitches of the vias penetrating through the metal layer may be reduced.

Further, since the via may be fined while the metal layer is formed to be thicker than the related art, warpage may be reduced and heat dissipation performance may be improved.

What is claimed is:

1. A circuit board comprising:
a first metal layer and a first via penetrating through the first metal layer,
wherein the first metal layer and the first via have an insulating film and a plated part provided therebetween.

2. The circuit board according to claim 1, wherein the plated part includes a plurality of plated layers.

3. A circuit board comprising:
a first metal layer having a first via hole penetrating through an upper surface of the first metal layer and a lower surface thereof;
a plated part provided to a surface of the first via hole;
an insulating film provided to a surface of the plated part; and
a first via formed of a conductive material and provided at least a portion of a region surrounded by an outer surface of the insulating film.

4. The circuit board according to claim 3, further comprising a second via hole defined by at least a portion of the outer surface of the insulating film has a shape corresponding to that of the first via hole and has a diameter smaller than that of the first via hole.

5. The circuit board according to claim 4, wherein the plated part includes a plurality of plated layers.

6. The circuit board according to claim 5, wherein each of the plurality of plated layers is formed by one plating process.

7. The circuit board according to claim 6, wherein the plating process is performed in a flash plating scheme.

8. The circuit board according to claim 5, further comprising:
a first conductor pattern provided to an outer surface of the first via;
a first insulating layer formed on the first metal layer and covering the first conductor pattern;
a second conductor pattern formed on the first insulating layer; and
a second via penetrating through the first insulating layer and having one side which is in contact with the first conductor pattern and the other side which is in contact with the second conductor pattern.

9. The circuit board according to claim 5, further comprising:
a first insulating layer formed on the first metal layer;
a second conductor pattern formed on the first insulating layer; and
a second via penetrating through the first insulating layer so as to be in contact with the first via.

10. The circuit board according to claim 9, further comprising:
a second insulating layer exposing at least a portion of the second conductor pattern; and
a connection portion provided in the second conductor pattern.

11. The circuit board according to claim 5, further comprising:
a first upper conductor pattern provided on the first via;
a first upper insulating layer covering the first upper conductor pattern;
a second upper conductor pattern formed on the first upper insulating layer; and
a second upper via penetrating through the first upper insulating layer and having one side which is in contact with the first upper conductor pattern and the other side which is in contact with the second upper conductor pattern.

12. The circuit board according to claim 11, further comprising:
a first lower conductor pattern provided below the first via;
a first lower insulating layer covering the first lower conductor pattern;
a second lower conductor pattern formed on the first lower insulating layer; and
a second lower via penetrating through the first lower insulating layer and having one side which is in contact with the first lower conductor pattern and the other side which is in contact with the second lower conductor pattern.

13. A circuit board comprising:
a first metal layer having a first via hole penetrating through an upper surface of the first metal layer and a lower surface thereof;
a plated part provided to a surface of the first via hole;
an insulating film provided to a surface of the plated part and having a second via hole surrounded by an outer surface of the insulating film; and
a first via provided in the second via hole.

14. The circuit board according to claim 13, wherein the plated part includes a plurality of plated layers which are each formed by one plating process.

15. The circuit board according to claim 13, wherein the first via hole includes:
a first upper via hole having a shape of which a width is decreased in a direction from the upper surface of the first metal layer to the lower surface thereof; and
a first lower via hole having a shape of which a width is decreased in a direction from the lower surface of the first metal layer to the upper surface thereof.

16. The circuit board according to claim 15, wherein the second via hole has a shape corresponding to that of the first via hole and has a diameter smaller than that of the first via hole.

17. A manufacturing method of a circuit board, the manufacturing method comprising:
forming a first via hole penetrating through a first metal layer;
forming a plated part on a surface of the first via hole;
forming an insulating film on a surface of the plated part; and
forming a first via made of a conductive material in a space surrounded by at least a portion of an outer surface of the insulating film.

18. The manufacturing method according to claim 17, wherein a second via hole defined by the at least a portion of the outer surface of the insulating film has a shape corresponding to that of the first via hole and has a diameter smaller than that of the first via hole.

19. The manufacturing method according to claim 18, wherein the forming of the plated part is performed by repeating a plating process for a plurality of times.

20. The manufacturing method according to claim 19, wherein the plating process is performed in a flash plating scheme.

21. A circuit board comprising:
a first metal layer including a hole penetrating through first and second surfaces of the first metal layer;
an electrically conductive via disposed in the hole;
a second metal layer interposed between the first metal layer and the electrically conductive via; and
an electrically insulating layer interposed between the second metal layer and the electrically conductive via.

22. The circuit board of claim 21, wherein an area of the electrically conductive via, determined in a plane parallel to one of the first and second surfaces of the first metal layer, first decreases and then increase along a path from the first surface to second surface of the first metal layer.

23. The circuit board of claim 21, wherein the electrically insulating layer completely surrounds the first metal layer.

24. The circuit board of claim 21, further comprising a first upper insulating layer and a first lower insulating layer disposed on the first and second surfaces of the first metal layer, respectively,
wherein:
each of the first upper insulating layer and the first lower insulating layer includes one hole overlapping the opening formed in the first metal layer, and
the electrically conductive via further extends along the holes formed in the first upper insulating layer and the first lower insulating layer.

25. The circuit board of claim 24, further comprising a plurality of metal traces formed at least on one of the first and second surface of the first metal layer, and interposed between the electrically insulating layer and the first upper insulating layer.

26. The circuit board of claim 24, further comprising:
a second upper insulating layer disposed on the first upper insulating layer and including a hole overlapping the hole formed in the first metal layer; and
a solder ball filling the hole of the second upper insulating layer.

27. The circuit board of claim 21, wherein the second metal layer includes a plurality of metal layers.

28. The circuit board of claim 21, wherein the electrically insulating layer is formed of parylene.
